(19) United States
(12) Patent Application Publication
(10) Pub. No.: US 2007/0235210 A1
(43) Pub. Date: Oct. 11, 2007

(54) Superconductive Composite Tape and a Method of Fabrication Thereof

(75) Inventors: Alberto Baldini, Firenze (IT); Armando Sbrana, Lucca (IT); Claudio Serracane, Lissone (IT); Sergio Zannella, Mariano Comense (IT)

Correspondence Address: VENABLE LLP, P.O. BOX 34385, WASHINGTON, DC, 20043-9998, US

(73) Assignee: EDISON S.P.A., Milano (IT)

(21) Appl. No.: 10/571,474

(22) PCT Filed: Sep. 10, 2004
(86) PCT No.: PCT/IB04/02954

§ 371 Date: Feb. 14, 2007

(30) Foreign Application Priority Data
Sep. 11, 2003 (IT) TO2003A000692

(51) Int. Cl. H01L 39/14

(52) U.S. Cl. 174/125.1; 427/309; 505/231

(57) ABSTRACT

There are provided herein a superconductive composite tape and a method of fabrication thereof: a tape having a layer made of superconductive material positioned on a substrate is etched, for example by using laser equipment, in order to obtain a plurality of grooves through the superconductive material layer and delimit a plurality of superconductive filaments, which are substantially parallel to one another and to a longitudinal axis of the tape and are spaced out from one another.

### TECHNICAL FIELD

The present invention relates to a superconductive composite tape and to a method of fabrication thereof.

### BACKGROUND ART

Superconductive composite tapes (so-called “coated conductors”) are of considerable industrial interest. In general terms, superconductive composite tapes are formed by a flexible metal substrate, one or more intermediate barrier or buffer layers, and a layer made of superconductive material, for example RE-Ba₂Cu₃O_{7-d} (REBCO) or YBa₂Cu₃O_{7-d} (YBCO).

Currently available superconductive composite tapes are not, however, fully satisfactory in terms of electrical and thermal stabilization and moreover present a relatively high dissipation of energy in the presence of currents and/or magnetic fields that vary in time. These drawbacks are particularly important for applications in the energy sector.

### DISCLOSURE OF INVENTION

A purpose of the present invention is consequently to provide a superconductive composite tape and a corresponding method of fabrication that will enable the drawbacks of the known art referred to above to be overcome.

A particular purpose of the invention is to provide a superconductive composite tape having good characteristics of electrical and thermal stabilization and low energy dissipation in the presence of currents and/or magnetic fields that vary in time.

A further purpose of the invention is to provide a method for obtaining said superconductive composite tape in a relatively simple, fast, and economically advantageous way.

In accordance with said purposes, the present invention relates to a superconductive composite tape and to a method of fabrication thereof, as defined in the annexed Claim 1 and Claim 14, respectively.

According to the invention, there is hence provided a superconductive composite tape, in which the layer made of superconductive material is divided into thin superconductive filaments, separated from one another. Splitting of the superconductive material into thin filaments enables both an electrical and thermal stabilization and the reduction in energy dissipation in the presence of currents and/or magnetic fields that vary in time.

The superconductive composite tape with multifilament structure according to the invention is hence suited to a particularly advantageous application in the energy sector.

### BRIEF DESCRIPTION OF THE DRAWINGS

Further characteristics and advantages of the present invention will emerge clearly from the description of the following non-limiting examples of embodiment, with reference to the figures of the annexed of drawings, in which:

FIG. 1 is a schematic illustration of a step of the method of fabrication of a superconductive composite tape according to the invention;

FIGS. 2 and 3 are schematic cross-sectional views of a superconductive composite tape in two subsequent steps of the method of fabrication according to the invention; and

FIG. 4 illustrates a preferred embodiment of the superconductive composite tape made according to the invention.

### BEST MODE FOR CARRYING OUT THE INVENTION

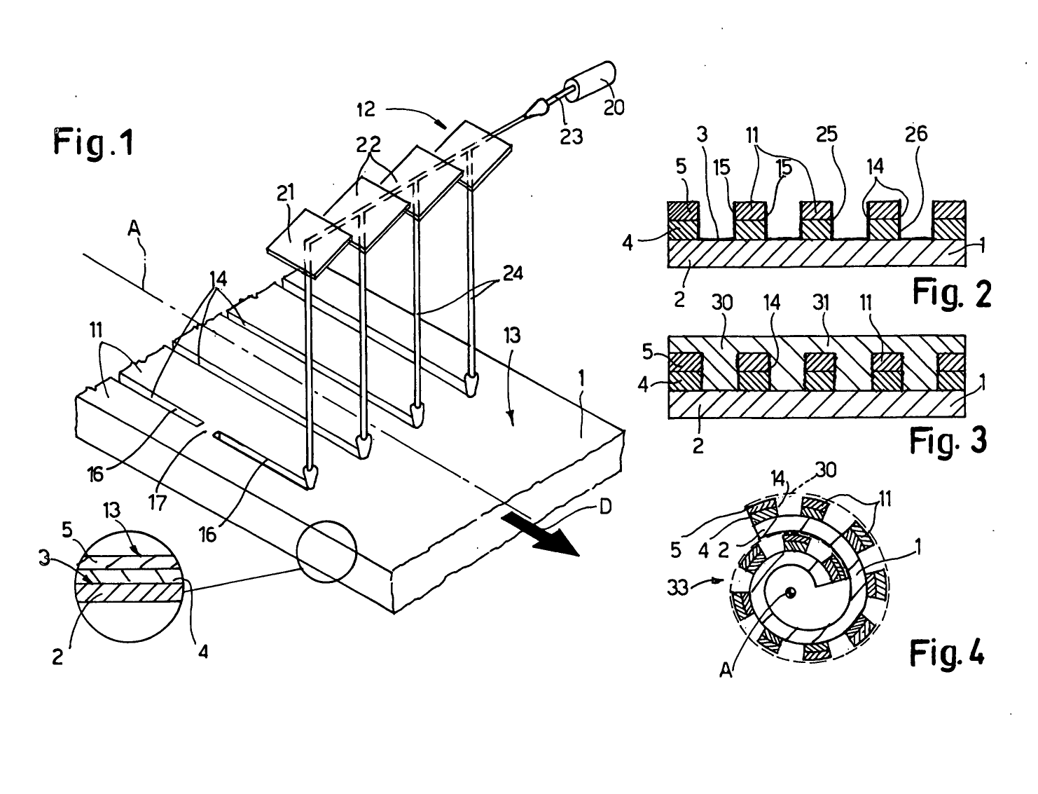

In FIG. 1, designated by 1 is a superconductive composite tape, comprising a substrate 2, in particular a ribbon-shaped flexible metal substrate (for example, an alloy of Ni, Cu, etc.), on a surface 3 of which there are deposited at least one intermediate buffer layer 4, made, for example, of metal oxide, and a layer 5 made of superconductive material, for example REBCO or YBCO.

The substrate 2 is provided with the buffer layer 4 and the layer 5 via known techniques of deposition.

The method according to the invention envisages then the formation in the layer 5 of a plurality of superconductive filaments 11, substantially parallel to one another and to a longitudinal axis A of the tape and laterally at a distance from one another.

In particular, the filaments 11 are formed in an etching step, schematically illustrated in FIG. 1. The tape 1 is fed continuously, in a direction of advance D parallel to the axis A, to a micro-etching apparatus 12, for example an apparatus for laser etching, set above a face 13 of the tape 1 defined by an outer surface of the layer 5. The apparatus 12 digs a plurality of grooves 14 through the layer 5 throughout the thickness of the layer 5 so as to delimit the filaments 11. Each filament 11 has a pair of side walls 15.

The grooves 14 can be continuous, i.e., extending substantially throughout the length of the tape 1, or else be constituted by discontinuous stretches 16, in such a way that each groove 14 is interrupted by a series of transverse bridges 17 made of superconductive material (only one of which is shown in FIG. 1 for reasons of simplicity) set for connection of adjacent filaments 11. The presence of the bridges 17 has positive effects in terms of electrical stabilization and reduces the leakages due to the coupling of the filaments 11.

In any case, as illustrated in detail in FIG. 2, the tape 1 is etched until the substrate 2 is reached and, hence, until the surface 3 is exposed. The grooves 14 are formed through the layer 5 and the buffer layer 4 and possibly penetrate slightly into the substrate 2 underneath the surface 3.

In the example illustrated in FIG. 1, the apparatus 12 comprises a laser source 20, operating in the visible and/or in the ultraviolet, and an optical assembly 21 that intercepts the beam 23 emitted by the source 20 and splits it, for example, via appropriately oriented plates 22, into a plurality of parallel beams 24 substantially orthogonal to the face 13, each of which etches a groove 14, removing the material with which it interacts.

The diameter, power, duration, and wavelength of the beams 23, 24 are selected so as to obtain grooves 14 of the required dimensions. For example, the grooves have a width of approximately 10-50 μm and a depth of 0.1-3 μm (and in any case such as to expose the substrate 2).

The bridges 17, if they are envisaged, are advantageously obtained, interrupting etching of the grooves at pre-set intervals during advance of the tape 1.

It remains understood that the grooves 14 can be etched with techniques other than laser etching, using micro-machining equipment of any known type.

Advantageously, the method according to the invention comprises also a step of providing the side walls 15 of the filaments 11 with resistive barriers 25.

In the case in point, the resistive barriers 25 are defined by respective portions 26 of a small thickness of the side walls 15. The portions 26 extend along the filaments 11 and within each filament 11. In each portion 26, the superconductive material has a structure modified with respect to the body of the layer 5 (i.e., of the filaments 11), and hence defines a resistive barrier 25.

In this case, the resistive barriers 25 are advantageously obtained in the etching step by modifying the structure of the superconductive material of the side walls 15. In general, the characteristics of the beam 23 and the process parameters of the etching step are selected in such a way as to prevent any excessive heating of the area surrounding the etches produced by the beams 24 in order to prevent excessive degradation of the materials of the layer 5, of the buffer layer 4, and of the substrate 2. However, a limited thermal degradation of said materials, and specifically of the superconductive material, in the strict proximity of the side walls 15 and in an area limited to the portions 26 brings about the desired formation of the resistive barriers 25.

Thanks to the presence of the resistive barriers 25, the filaments 11 are electromagnetically uncoupled from one another.

According to a preferred embodiment, schematically illustrated in FIG. 3, the method according to the invention then comprises a coating step, in which the filaments 11 are embedded in a coating material, in particular a metal material that is highly conductive both from the electrical standpoint and from the thermal standpoint (for example, Cu, Ag, Au, etc.), which forms a coating 30 of a thickness of a few micron on the tape 1.

In the coating step, the coating material is introduced into the grooves 14 and fills the grooves 14 completely, and is moreover deposited on the face 13 to coat the filaments 11.

Each individual filament 11 is consequently embedded in a metal matrix 31, each filament 11 being surrounded on three sides by the coating material, which, in turn, is in direct contact with the underlying metal substrate 2.

In this way, a highly stabilized structure is obtained.

A preferred embodiment, schematically illustrated in FIG. 4, then envisages that the tape 1, already provided with the grooves 14 delimiting the filaments 11 and possibly with the coating 30 (represented by a dashed line in FIG. 4), is sent on to a winding step, in which the tape 1 is wound on itself about the axis A in a transverse direction so as to form a superconductive thread 33 with a multifilament structure, in which the filaments 11 are substantially parallel to one another and to the axis A.

Alternatively, a step of twisting of the tape 1 on itself along the axis A is envisaged so as to form a tress-like thread 33, in which the filaments 11 are substantially spirally wound with respect to one another.

Preferably, the tape 1 is first of all wound on itself about the axis A to form a thread 33 with parallel filaments 11, and subsequently the thread 33 is in turn twisted on itself to form a tress along the axis A. There is in this way achieved an advantageous effect of reduction of the leakages.

1. A superconductive composite tape (1), comprising a substrate (2) and a layer (5) made of superconductive material, said superconductive material layer (5) comprising a plurality of superconductive filaments (11), which are substantially parallel to one another and to a longitudinal axis (A) of the tape and are spaced out from one another; the tape being characterized in that it comprises a coating (30) made of a conductive coating material, the filaments (11) being embedded in the coating (30); and in that each filament (11) is delimited by a pair of side walls (15) provided with resistive barriers (25).

2. The tape according to claim 1, characterized in that the resistive barriers (25) are defined by respective portions (26) of the side walls (15) in which the superconductive material has a structure modified with respect to the body of the superconductive material layer (5).

3. The tape according to claim 1, characterized in that the filaments (11) are separated from one another by grooves (14) formed through said superconductive material layer (5) throughout the whole thickness of said superconductive material layer (5).

4. The tape according to claim 3, characterized in that the grooves (14) are interrupted by transverse bridges (17) for connection between adjacent filaments (11).

5. The tape according to claim 3, characterized in that the grooves (14) extend in depth up to the substrate (2).

6. The tape according to claim 3, characterized in that it comprises at least one buffer layer (4), interposed between the substrate (2) and the superconductive material layer (5), the grooves (14) extending through the superconductive material layer (5) and through the buffer layer (4) up to the substrate (2).

7. The tape according to claim 1, characterized in that the coating material is a metal material.

8. The tape according to claim 1, characterized in that the coating (30) fills the grooves (14) and coats the filaments (11).

9. The tape according to claim 1, characterized in that it is wound on itself around said axis (A) to form a thread (33) in which said filaments (11) are substantially parallel to said axis (A).

10. The tape according to claim 1, characterized in that it is twisted on itself along said axis (A) to form a tress-like thread (33), in which the filaments (11) are substantially spirally wound with respect to one another.

11. The tape according to claim 1, characterized in that the filaments (11) are connected to one another by transverse bridges (17) made of superconductive material.

12. A method of fabrication of superconductive composite tapes, comprising a step of providing a superconductive composite tape (1) having a superconductive material layer (5) positioned on a substrate (2), and a step of forming in the superconductive material layer (5) a plurality of superconductive filaments (11) delimited by respective pair of side walls (15), the filaments (15) being substantially parallel to one another and to a longitudinal axis (A) of the tape and being spaced out from one another; the method being characterized by further comprising a step of providing the side walls (15) of the filaments (11) with resistive barriers (25), and a coating step, in which the filaments (11) are embedded in a conductive coating material that forms a coating (30) of the tape (1).

13. The method according to claim 12, characterized by comprising an etching step, in which a plurality of grooves (14) is dug through the superconductive material layer (5) throughout the whole thickness of said superconductive material layer (5) in order to delimit the filaments (11); said resistive barriers (25) being formed in said etching step, by modifying the structure of the superconductive material of said side walls (15).

14. The method according to claim 13, characterized in that, in the etching step, the grooves (14) are dug in discontinuous stretches, in such a way that each groove (14) is interrupted by transverse bridges (17) connecting adjacent filaments.

15. The method according to claim 13, characterized in that, in the etching step, the tape (1) is dug up to the substrate (2).

16. The method according to claim 13, characterized in that the tape (1) comprises at least one buffer layer (4) set between the substrate (2) and the superconductive material layer (5), and the etching step is carried out through the superconductive material layer (5) and through the buffer layer (4) up to the substrate (2).

17. The method according to claim 12, characterized in that the coating material is a metal material.

18. The method according to claim 12, characterized in that, in said coating step, the coating material fills said grooves (14) and coats said filaments (11).

19. The method according to claim 12, characterized in that it comprises a step of winding the tape (1) on itself about said axis (A) to form a thread (33) in which the filaments (11) are substantially parallel to said axis (A).

20. The method according to claim 12, characterized in that it comprises a step of twisting the tape (1) on itself along said axis (A) to form a tress-like thread (33) in which said filaments (11) are substantially spirally wound with respect to one another.

21. The method according to claim 12, characterized in that it comprises a step of connecting the filaments (11) to one another via transverse bridges (17) made of superconductive material.
